(19) United States
(12) Patent Application Publication
(10) Pub. No.: US 2026/0285458 A1
(43) Pub. Date: Sep. 24, 2026

(54) Enclosed Volume Cooling System

(71) Applicant: USA AS REPRESENTED BY THE SEC OF THE NAVY, San Diego, CA (US)

(72) Inventor: Nathan Cohen, San Diego, CA (US)

(73) Assignee: USA AS REPRESENTED BY THE SEC OF THE NAVY, San Diego, CA (US)

(21) Appl. No.: 19/034,978

(22) Filed: Jan. 23, 2025

(51) Int. Cl. B63G 8/36; H05K 7/20

(52) U.S. Cl. CPC B63G 8/36; H05K 7/20145; H05K 7/20209; H05K 7/20236; H05K 7/20863; H05K 7/20872

(57) ABSTRACT

Embodiments of the present invention include a system and method for managing heat produced by electronic components on an enclosure where a fluid stream is directed to the electrical components and where the resulting hot air is cooled by a heat sink conductively coupled to an outside surface of the enclosure.

### FEDERALLY-SPONSORED RESEARCH AND DEVELOPMENT

The United States Government has ownership rights in this invention. Licensing and technical inquiries may be directed to the Office of Research and Technical Applications, Naval Information Warfare Center Pacific, Code 72120, San Diego, CA, 92152; voice: (619) 553-5118; email: NIWC_Pacific_T2@navy.mil. Reference Navy Case Number 211802.

### BACKGROUND OF THE INVENTION

Cooling systems within enclosures such as vehicles are often used to cool equipment such as electrical components. The electrical components can perform functions such as energy storage, navigation, sensing and communications. In an environment where an enclosure has free flowing air from the atmosphere, passive cooling devices are often sufficient to meet the needs of cooling electrical components.

When passive cooling may not be sufficient, there exists a need in the art for improved cooling performance.

### SUMMARY OF THE INVENTION

In an embodiment, a system for managing heat produced by electronic components on a vehicle, includes a convection device configured to move a fluid stream past at least one electronic component located onboard the vehicle, and a heat sink in thermal communication with the fluid stream and in thermal communication with an exterior of the vehicle where the heat sink is located downstream of the electronic components.

In an embodiment, a method for managing heat produced by electronic components on a vehicle, includes moving a fluid stream past at least one electronic component located onboard the vehicle to produce hot air, and moving the hot air to a heat sink in thermal communication with the fluid and in thermal communication with an exterior of the vehicle, the heat sink located downstream of the electronic components.

### BRIEF DESCRIPTION OF THE DRAWINGS

The following drawings illustrate exemplary embodiments for carrying out the invention. Like reference numerals refer to like parts in different views or embodiments of the present invention in the drawings.

FIG. 1 is a functional diagram illustrating a system for managing heat produced by electronic components, according to one or more embodiments of the present invention.

FIG. 2 is a perspective view of a system for managing heat produced by electronic components and electronic components, according to one or more embodiments of the present invention.

FIG. 3 is side cutaway view of a system for managing heat produced by electronic components and electronic components, according to one or more embodiments of the present invention.

FIG. 4 illustrates a heat sink according to one or more embodiments of the present invention.

FIG. 5 is a flowchart of a method for managing heat produced by electronic components according to one or more embodiment of the present invention.

### DETAILED DESCRIPTION

The disclosed methods and systems below may be described generally, as well as in terms of specific examples and/or specific embodiments. For instances where references are made to detailed examples and/or embodiments, it should be appreciated that any of the underlying principles described are not to be limited to a single embodiment, but may be expanded for use with any of the other methods and systems described herein as will be understood by one of ordinary skill in the art unless otherwise stated specifically.

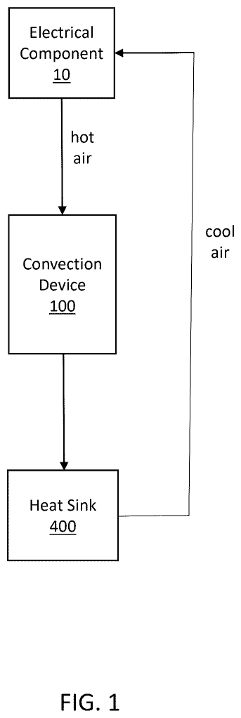

FIG. 1 is a functional diagram for a system for managing heat produced by electronic components on a vehicle. In an embodiment, the system comprises a convection device 100 configured to move a fluid stream such as cool air past at least one electronic component 10 located onboard the vehicle to produce hot air and a heat sink 400 in thermal communication with the fluid stream and in thermal communication with an exterior of the vehicle, where the heat sink is located downstream of the electronic components. A single electronic component may need to be cooled or multiple electronic components may need to be cooled. In an embodiment, the vehicle is an enclosure which may be moved or towed by another vehicle or mechanism which is separate from the enclosure.

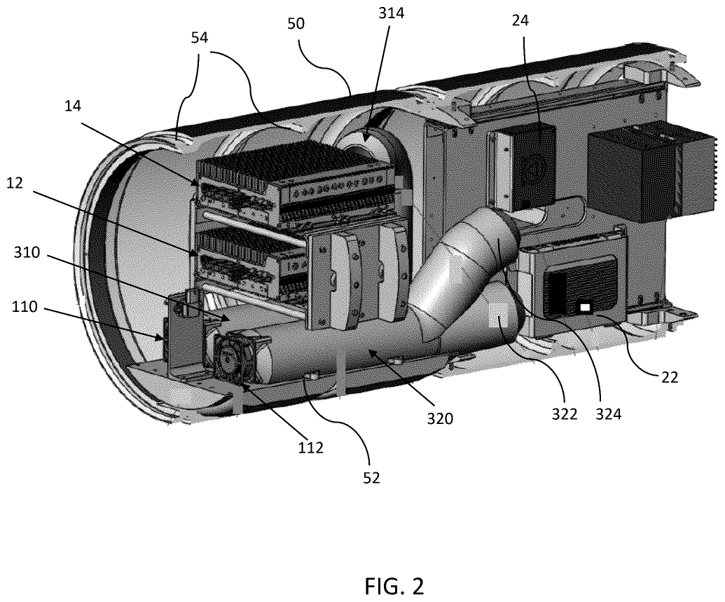

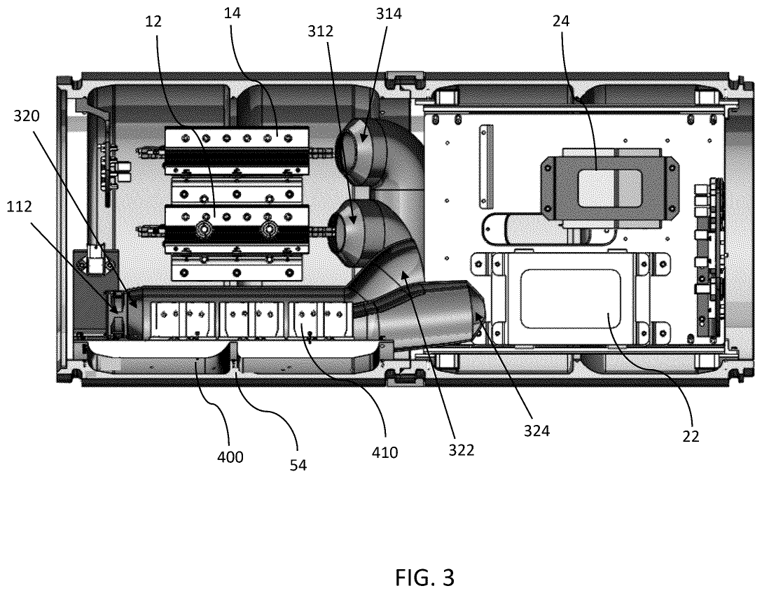

In an embodiment, the vehicle is an underwater vehicle that is hermetically sealed when in operational use, for example, underwater, such that the ambient water serves as a cool well In this embodiment, a fluid stream is recirculated within the vehicle in alternating states of cool air and hot air. Referring to FIG. 2 and FIG. 3, the vehicle may have a fuselage 50 that has a portion that is oval in shape. The vehicle may generally be cylindrical in shape being longer longitudinally than laterally with an oval or circular cross-section. One or more electronic components 12, 14, 22, 24 may be located in a front to back arrangement. For example, a first set of electronic components 12, 14 may be located longitudinally within the fuselage 50 in front of or behind a second set of electronic components 22, 24 along the length of the fuselage. The underwater vehicle may be manned or unmanned. In an unmanned embodiment, since there is no need to provide room for a human to occupy, there is typically a smaller volume of air relative to the heat generated by electronic equipment aboard the hermetically sealed vehicle as compared to a manned vehicle, making the need for an active cooling system higher.

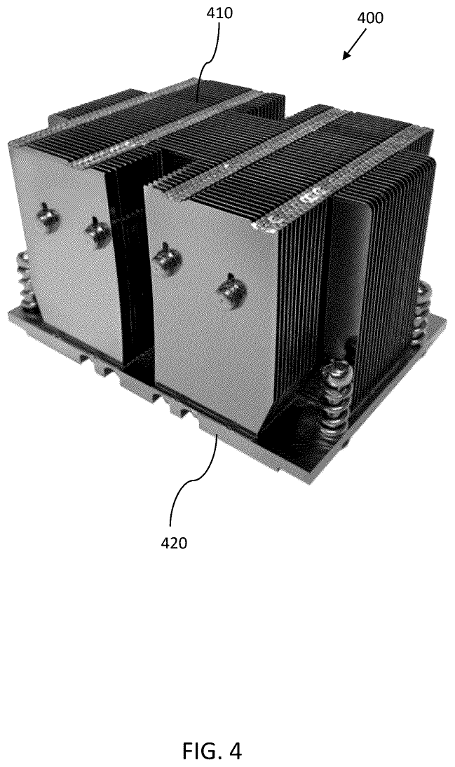

In an embodiment, the heat sink 400 is conductively coupled to the exterior of the vehicle, such as through the fuselage 50. The heat sink may be made of metal such as aluminum or copper. Referring also to FIG. 4, the heat sink 400 may include a number of heat pipes and/or fins 410 which are coupled to conductive base 420. The conductive base 420 of the heat sink may be connected directly or indirectly to a conductive or metal portion of the fuselage 50. The fuselage 50 may be made of a metal or may be made of a composite or a plastic that has conductive portions at which the conductive base 420 is conductively coupled and to which the conductive portions are conductively in contact with an exterior of the vehicle. In an embodiment, the conductive base 420 has at least a portion that is complimentary in shape to an inner side of the fuselage 50 such that the area of contact between a side of the conductive base 420, e.g. the bottom side in FIG. 2, and the inner portion is increased as compared to having discrete points of contact with the inner portion through electrical leads.

The vehicle may have a fuselage 50 that has a portion that is oval in shape and the heat sink 400 may lie within the oval-shaped portion. In an embodiment, the heat sink 400 lies below a floor 52 located within the fuselage 50 where the oval shape of the fuselage provides both a floor and sidewalls that define a well, within which the heat sink lies. The floor 52 may serve the purpose of provide a mounting surface for an electrical component or the racks which hold the electrical components. In another embodiment, the heat sink is located in a ceiling of the fuselage 50 which would be at the top of the fuselage when the vehicle is in an upright orientation. In an embodiment, the heat sink is located a within a wall which would be on a side of the fuselage when the vehicle is in an upright orientation. In an embodiment, the heat sink 400 or portions of the heat sink lie between fuselage structural elements such as the frames 54 or stringers.

Referring to FIG. 2 and FIG. 3, in an embodiment, the convection device 100 includes one or more fans 110, 112 including fans that have rotating blades. The convection device 100 may further include one or more ducts and the ducts may be formed through 3D printing. A duct may move a fluid stream through multiple openings. Multiple unconnected ducts 310, 320 may be used where each duct directs a fluid stream through separate openings 312, 314 and 322, 324 to separate electronic components, 12, 14 and 22, 24 respectively. In an embodiment, a duct opening is within two feet of an electrical component. The ducts may linearly extend within twenty degrees of each other along a portion of the length of a cylindrically-shaped fuselage of the vehicle. In an embodiment, the ducts extend in parallel with each other in an abutting relationship for at least a portion of their length. This embodiment would provide the benefit of reducing unused space in the vehicle.

Ducts 310 and 320 ingest the hot air on a hot side of the duct where fans 110 and 112 are located. The hot air then passes through the heat pipes and/or fins 410 of the heat sink 400 to produce cooling air downstream of the heat sink that then exits through openings 312, 314, 322, 324. While in this embodiment illustrates a single heat sink that is in thermal communication with a plurality of fluid streams, the heat sinking features can be divided into multiple individual heat sinks for purposes that can include physical fit within the vehicle, lower production cost or ease of installation. While fans 110 and 112 are shown in a pushing configuration at the start of a flow stream through ducts 310 and 320, fans may also be located at the outlet of a duct in a pulling configuration.

In an embodiment, a first duct of the convection device directs a fluid stream in a direction within twenty degrees of the opposite direction of a second duct. Referring to FIG. 2 and FIG. 3 ducts 312 and 314 direct a cooling fluid stream towards the left, while ducts 322 and 324 direct a cooling fluid stream to the right. This configuration of the ducts would be of benefit for vehicles where it is desired to arrange electrical components in a spaced-apart fashion such as along the length of a cylindrically-shaped vehicle while desiring to have a single or co-located set of heat sinks such that multiple ducts direct hot air to a common area where a heat sink is located.

In embodiment, the downstream flow from a first electronic component is a portion of the upstream flow of a second electronic component electrical component. Referring to FIG. 2 and FIG. 3, duct openings 322 and 324 provide cooling air to electrical components 22 and 24. After passing over electrical components 22 and 24 the fluid stream becomes hot air and this fluid stream of hot air moves from electrical components 22 and 24 to the ingestion points for ducts 310 and 320, which are at fans 110 and 112. Along this path, the hot air fluid stream from electrical components 22 and 24 will become part of the upstream fluid stream from ducts 312 and 314 that cools electrical components 12 and 14.

In an embodiment, the operating temperature of one component is greater than the operating temperature of a second electronic component. In this embodiment, the hot air produced by cooling a first electrical component of a lower temperature would be cooler than the hot air produced by a second electrical component assuming that each component has a similar heat producing surface. Thus, in this embodiment, the hot air produced by the first cooler operating electrical component could be used to cool a second electronic component that operates at a higher temperature as hot air from the cooler operating electronic component would be at a lower temperature than the operating temperature of the second electronic component.

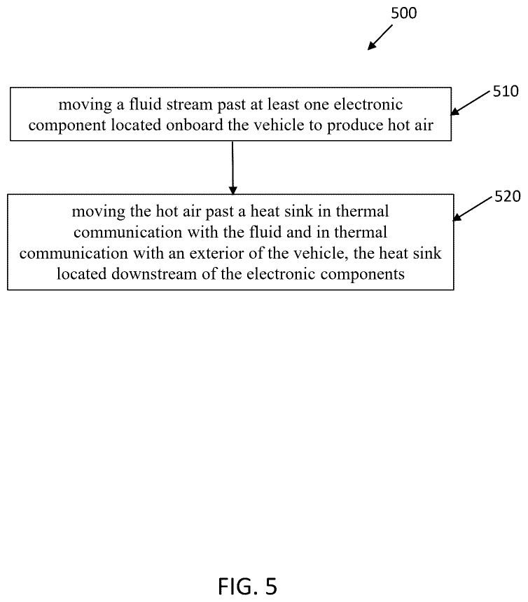

FIG. 5 is a flowchart illustrating a method for managing heat produced by electronic components on a vehicle 500. The method comprises moving a fluid stream past at least one electronic component located onboard the vehicle to produce hot air 510 and moving the hot air past a heat sink in thermal communication with the hot air and in thermal communication with an exterior of the vehicle, the heat sink located downstream of the electronic components 520.

The method, in the step of moving a fluid stream past at least one electronic component located onboard the vehicle, may include moving a fluid stream through a plurality of unconnected ducts, each duct directing a fluid stream to a separate electronic component. The method, in the step of moving a fluid stream past at least one electronic component located onboard the vehicle may include a first duct directing a first fluid stream in a direction within twenty degrees of the opposite direction of a second fluid stream directed by a second duct.

The structure corresponding to the recited function being understood to be the structure corresponding to that function and the equivalents thereof permitted to the fullest extent of this written description, which includes the accompanying claims and the drawings as interpreted by one of skill in the art.

In understanding the scope of the present invention, the term “configured” as used herein to describe a component, section or part of a device includes hardware and/or software that is constructed and/or programmed to carry out the desired function. In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. Finally, terms of degree such as “substantially”, “about”, “generally” and “approximately” as used herein mean a reasonable amount of deviation of the modified term such that the end result is not significantly changed.

From the above description, it is manifest that various techniques may be used for implementing the concepts without departing from the scope of the claims. The described embodiments are to be considered in all respects as illustrative and not restrictive. The method/apparatus disclosed herein may be practiced in the absence of any element that is not specifically claimed and/or disclosed herein. It should also be understood that the systems and methods are not limited to the particular embodiments described herein, but is capable of many embodiments without departing from the scope of the claims.

What is claimed is:

1. A system for managing heat produced by electronic components on a vehicle, comprising:
a convection device configured to move a fluid stream past at least one electronic component located onboard the vehicle; and
a heat sink in thermal communication with the fluid stream and in thermal communication with an exterior of the vehicle, where the heat sink located downstream of the electronic components.

2. The system of claim 1 where the vehicle is hermetically sealed.

3. The system of claim 1 where the heat sink is conductively coupled to the exterior of the vehicle.

4. The system of claim 1 where a metal portion of the exterior of the vehicle is conductively coupled to the heat sink.

5. The system of claim 1 where the vehicle has fuselage that has a portion that is oval in shape and the heat sink lies within the oval-shaped portion.

6. The system of claim 1 where convection device includes a duct which was formed through 3D printing.

7. The system of claim 1 where the convection device has a plurality of unconnected ducts each duct directing a fluid stream to a separate electronic component.

8. The system of claim 1 where the downstream flow from a first electronic component is a portion of the upstream flow of a second electronic component.

9. The system of claim 1 where a single heat sink is in thermal communication with a plurality of fluid streams.

10. The system of claim 1 where the operating temperature of one component is greater than the operating temperature of a second electronic component.

11. The system of claim 1 where the heat sink includes heat pipes coupled to metal fins.

12. The system of claim 1 where the heat sink is located in one of a ceiling, a wall or below a floor of the fuselage.

13. The system of claim 1 where ducts of the convection device linearly extend within twenty degrees of each other along a portion of the length of a cylindrically-shaped fuselage of the vehicle.

14. The system of claim 1 where the vehicle is an underwater vehicle.

15. The system of claim 1 where a first electronic component is arranged in a front to back arrangement with a second electronic component.

16. The system of claim 1 where the end of a duct is within two feet of an electronic component.

17. The system of claim 1 where a first duct of the convection device directs a fluid stream in a direction within twenty degrees of the opposite direction of a second duct.

18. A method for managing heat produced by electronic components on a vehicle, comprising
moving a fluid stream past at least one electronic component located onboard the vehicle to produce hot air; and
moving the hot air a heat sink in thermal communication with the fluid and in thermal communication with an exterior of the vehicle, the heat sink located downstream of the electronic components.

19. The method of claim 18 where in the step of moving a fluid stream past at least one electronic component located onboard the vehicle comprises moving a fluid stream through a plurality of unconnected ducts, each duct directing a fluid stream to a separate electronic component.

20. The method of claim 18 where in the step of moving a fluid stream past at least one electronic component located onboard the vehicle comprises a first duct directing a first fluid stream in a direction within twenty degrees of the opposite direction of a second fluid stream directed by a second duct.
